(19) United States
(12) Patent Application Publication
(10) Pub. No.: US 2025/0266342 A1
(43) Pub. Date: Aug. 21, 2025

(54) MANUFACTURING METHOD FOR THIN WIRING MEMBER, THIN WIRING MEMBER, AND MANUFACTURING METHOD FOR WIRING BOARD

(71) Applicant: Resonac Corporation, Minato-ku, Tokyo (JP)

(72) Inventors: Keiichi HATAKEYAMA, Minato-ku, Tokyo (JP); Kazuyuki MITSUKURA, Minato-ku, Tokyo (JP); Katsuhiko SUZUKI, Minato-ku, Tokyo (JP); Hiroyoshi DEGUCHI, Minato-ku, Tokyo (JP)

(21) Appl. No.: 18/857,186

(22) PCT Filed: Apr. 28, 2022
(86) PCT No.: PCT/JP2022/019395

§ 371 Date: Oct. 16, 2024

(51) Int. Cl. H01L 23/498; H01L 21/48

(52) U.S. Cl. CPC H01L 23/49833; H01L 21/4857; H01L 23/49822; H01L 23/49838

(57) ABSTRACT

Disclosed is a method for manufacturing a plurality of thin wiring members. The method for manufacturing a plurality of thin wiring members includes, preparing a first carrier, fabricating a wiring layer on the first carrier, the wiring layer including a plurality of wiring portions corresponding to the plurality of thin wiring members and an insulating portion present around the plurality of wiring portions, forming a support layer harder than the insulating portion of the wiring layer, and singulating a wiring body including the wiring layer and the support layer such that each singulated wiring body includes at least one wiring portion of the plurality of wiring portions.

### TECHNICAL FIELD

The present disclosure relates to a method for manufacturing a thin wiring member, a thin wiring member, and a method for manufacturing a wiring board.

### BACKGROUND ART

Patent Literature 1 discloses an example of a fan-out semiconductor device. In this semiconductor device, a redistribution layer is disposed between a semiconductor chip and external connection terminals, and the redistribution layer increases spaces between the semiconductor chip and the terminals, thereby enabling connection with the external connection terminals.

### CITATION LIST

### Patent Literature

Patent Literature 1: Japanese Unexamined Patent Publication No. 2019-029557

### SUMMARY OF INVENTION

### Technical Problem

In a method in the related art, a redistribution layer is formed on a board, but it is difficult to make the redistribution layer fine due to, for example, large variations in height of the board. To address this problem, studies have been conducted on a method in which a redistribution layer including a fine wiring is fabricated by patterning on a flat glass carrier, followed by transferring the redistribution layer. However, the redistribution layer is an adhesive and elastic member which has a small thickness of, for example, 50 μm and an unstable shape and is difficult to handle at the time of transferring. More specifically, if a large number of redistribution layers are to be collectively fabricated on a glass carrier, it is necessary to singulate a redistribution layer into individual redistribution layers, but it is difficult to perform accurate dicing at the time of singulation.

An object of the present disclosure is to provide a method for manufacturing a thin wiring member, a thin wiring member, and a method for manufacturing a wiring board, which enables accurate singulation of a wiring member having a small thickness and an unstable shape.

### Solution to Problem

An aspect of the present disclosure relates to a method for manufacturing a thin wiring member. The method is a method for manufacturing a plurality of thin wiring members. The method includes preparing a first carrier, fabricating a wiring layer on the first carrier, the wiring layer including a plurality of wiring portions corresponding to the plurality of thin wiring members and an insulating portion present around the plurality of wiring portions, forming a support layer harder than the insulating portion of the wiring layer, and singulating a wiring body including the wiring layer and the support layer such that each singulated wiring body includes at least one wiring portion of the plurality of wiring portions.

In the method for manufacturing a thin wiring member, the support layer harder than the insulating portion of the wiring layer is formed, and the wiring body including the wiring layer and the support layer is singulated in such a manner that each singulated wiring body includes at least one wiring portion of the plurality of wiring portions. In this case, it is possible to perform singulation in a state where the wiring layer having an unstable shape is supported by the hard support layer. Accordingly, this manufacturing method enables accurate singulation of a wiring member that has a small thickness and an unstable shape. If the wiring layer is thin, an impact or the like during the singulation (for example, dicing) may turn the wiring layer up. However, according to this manufacturing method, the support layer supporting the wiring layer prevents such a problem. In the method for manufacturing a thin wiring member, the wiring body may be singulated in the singulating in a state where the support layer is bonded to the entire surface of the wiring layer.

In the method for manufacturing a thin wiring member, the wiring body may be singulated by dicing with a blade from the support layer toward the wiring layer in the singulating. In this case, the dicing is performed from the hard support layer side, and the wiring layer which has an unstable shape and is to be cut subsequently to the support layer can be diced accurately with the blade, thereby enhancing the dicing performance.

In the method for manufacturing a thin wiring member, the wiring body may be singulated by dicing in a state where the wiring layer is sandwiched between the first carrier and the support layer in the singulating. In this case, the dicing is performed in a state where the wiring layer having an unstable shape is sandwiched and fixed between the first carrier and the hard support layer so as not to move, thereby enabling the dicing with higher accuracy.

The method for manufacturing a thin wiring member may further include bonding the singulated wiring body to an adhesive film, removing the first carrier from the wiring body bonded to the adhesive film, and dividing the adhesive film to which the singulated wiring body is bonded. With regard to a dividing method, employable examples include burning with a laser, dividing with a blade, and dividing by expansion. In this manufacturing method, the adhesive film may be bonded to the support layer of the wiring body in the bonding, and the adhesive film may be separated along a cutting region in the support layer in the dividing. In this case, it is possible to prevent reduction of dimensional accuracy which is caused when the wiring layer having an unstable shape is pulled by the separation of the adhesive film at the time of division. Accordingly, this manufacturing method makes it possible to keep high dimensional accuracy of the thin wiring member.

In the method for manufacturing a thin wiring member, the support layer may be formed on the first carrier in the forming of the support layer, and the wiring layer may be fabricated on the support layer in the fabricating of the wiring layer. In this case, the wiring layer having an unstable shape can be fixed more reliably by the hard support layer and singulated. Accordingly, this manufacturing method enables accurate singulation.

In the method for manufacturing a thin wiring member, the wiring body may be singulated by dicing with a blade from the wiring layer toward the support layer in the singulating. In this case, although the dicing is performed from the wiring layer, the wiring layer is firmly supported by the hard support layer on the opposite surface, thereby enabling the dicing in a state where the wiring layer is fixed to some extent. Accordingly, this manufacturing method enables accurate dicing of the wiring member that has a small thickness and an unstable shape. In addition, if the wiring layer is thin, it is assumed that the wiring layer is turned up by water pressure during the dicing, but such a problem is prevented by disposing the support layer under the wiring layer.

The method for manufacturing a thin wiring member may include bonding a second carrier to a surface of the wiring layer opposite to a surface to which the support layer is bonded, removing the first carrier after bonding the second carrier, and bonding, to an adhesive film, the wiring body to which the second carrier is bonded. In the singulating, the wiring layer, the support layer, and the adhesive film may be singulated by dicing after being bonded to the adhesive film. In this case, it is possible to remove the first carrier to which the support layer is bonded, thereby enabling removal of the support layer by etching or the like. In addition, there is no need to expand the adhesive film because the dicing is performed up to the adhesive film, thereby preventing reduction of dimensional accuracy of the wiring layer accompanied by the separation of the adhesive film at the time of expansion of the adhesive film.

The method for manufacturing a thin wiring member may further include removing the second carrier. The wiring layer, the support layer, and the adhesive film may be singulated in the singulating by dicing after the second carrier is removed. In this case, there is no need to dice the second carrier, and the material of the second carrier can be selected more freely. The non-necessity of dicing the second carrier increases the speed of dicing, which enhances the efficiency of fabrication.

In the method for manufacturing a thin wiring member, the second carrier, the wiring layer, the support layer, and the adhesive film may be singulated by dicing in the singulating. In this case, the dicing is performed in a state where the wiring layer having an unstable shape is sandwiched and fixed between the second carrier and the hard support layer so as not to move, thereby enabling the dicing with accuracy.

In the method for manufacturing a thin wiring member, the wiring layer may have a thickness of 200 μm or less. In this case, the thin wiring member can be reliably made thinner. Even with the wiring layer having a thickness of 200 μm or less, the manufacturing method according to any one of the aforementioned descriptions enables accurate singulation of the wiring body that has the wiring layer having an unstable shape.

In the method for manufacturing a thin wiring member, the support layer may have a thickness 25% or more and 3000% or less of a thickness of the wiring layer. With the support layer having a thickness 25% or more of the thickness of the wiring layer, the wiring layer that has an unstable shape is firmly supported by the support layer, which enables accurate singulation. In addition, with the support layer having a thickness 3000% or less of the thickness of the wiring layer, it is possible to keep the thin wiring member thin without increasing the thickness.

In the method for manufacturing a thin wiring member, the support layer may be formed of a material having a flexural modulus of 3 GPa or more (or a flexural strength of 700 MPa or more). In this case, at the time of singulation, the wiring layer having an unstable shape is reliably supported by the hard support layer. Accordingly, this manufacturing method enables accurate singulation.

In the method for manufacturing a thin wiring member, the support layer may include a thermosetting resin layer containing an inorganic filler. In this case, the inorganic filler enables the blade to exert its self-sharpening action. The thermosetting resin layer in this case preferably contains the inorganic filler in an amount of 40 mass % or more and 90 mass % or less. Accordingly, the wiring layer achieves both supporting and cutting properties. The inorganic filler preferably has an average particle size of 0.05 μm or more, and more preferably, 0.1 μm or more.

In the method for manufacturing a thin wiring member, the first carrier may be a glass carrier having arithmetic average roughness of 50 nm or less. In this case, the wiring layer fabricated on the first carrier can be made fine with accuracy.

In the method for manufacturing a thin wiring member, the wiring layer may include a wiring having a line width of 5 μm or less. In this case, it is possible to obtain a thin wiring member having a fine wiring.

The present disclosure also relates to a thin wiring member as another aspect. The thin wiring member includes a wiring layer having a wiring and a resin composition present around the wiring or a cured product of the resin composition, and a support layer disposed on a surface of the wiring layer. In this thin wiring member, the support layer is formed of a material harder than the resin composition of the wiring layer or the cured product of the resin composition.

The thin wiring member has the support layer formed of a material harder than the resin composition of the wiring layer or the cured product of the resin composition. In this case, it is possible to prevent the thin wiring member from being warped or rounded when manufacturing a wiring board or a semiconductor device using the thin wiring member, which enables shape stabilization.

In the thin wiring member, the wiring layer may have a thickness of 200 μm or less, the support layer may have a thickness of 50 μm or more and 1200 μm or less, and the wiring layer may include a wiring having a line width of 5 μm. In this case, the thin wiring member is made to have a fine wiring.

In the thin wiring member, the support layer may be formed of a material having a flexural modulus of 3 GPa or more (or a flexural strength of 700 MPa or more). In this case, it is possible to prevent the thin wiring member more reliably from being warped or rounded, which enables shape stabilization.

In the thin wiring member, the support layer may include a thermosetting resin layer containing an inorganic filler. The thermosetting resin layer in this case may contain the inorganic filler in an amount of 40 mass % or more and 90 mass % or less. In this case, the wiring layer achieves both supporting and cutting properties.

The present disclosure relates to a method for manufacturing a wiring board as yet another aspect. The method for manufacturing a wiring board includes preparing a thin wiring member manufactured by the method for manufacturing a thin wiring member according to any one of the aforementioned descriptions, placing the thin wiring member on a board or in the board, and connecting the wiring of the thin wiring member to a connection terminal.

### Advantageous Effects of Invention

According to the present disclosure, it is possible to accurately singulate to a wiring member that has a small thickness and an unstable shape.

### BRIEF DESCRIPTION OF DRAWINGS

FIG. 1 is a cross-sectional view illustrating an example of a thin wiring member.

FIGS. 2A, 2B and 2C are views sequentially illustrating a method for manufacturing the thin wiring member illustrated in FIG. 1.

FIGS. 3A, 3B and 3C are views sequentially illustrating the method for manufacturing the thin wiring member illustrated in FIG. 1, illustrating steps taken after the steps in FIGS. 2A to 2C.

FIGS. 4A, 4B and 4C are views sequentially illustrating the method for manufacturing the thin wiring member illustrated in FIG. 1, illustrating steps taken after the steps in FIGS. 3A to 3C.

FIGS. 5A, 5B and 5C are views sequentially illustrating a method for manufacturing a wiring board using the thin wiring member.

FIGS. 6A, 6B and 6C are views sequentially illustrating another method for manufacturing the thin wiring member illustrated in FIG. 1.

FIGS. 7A, 7B and 7C are views sequentially illustrating the method for manufacturing the thin wiring member illustrated in FIG. 1, illustrating steps taken after the steps in FIGS. 6A to 6C.

FIGS. 8A, 8B and 8C are views sequentially illustrating the method for manufacturing the thin wiring member illustrated in FIG. 1, illustrating steps taken after the steps in FIGS. 7A to 7C.

FIGS. 9A, 9B and 9C are views sequentially illustrating yet another method for manufacturing the thin wiring member illustrated in FIG. 1, illustrating steps taken after the steps in FIG. 7A to 7C.

FIGS. 10A, 10B, 10C and 10D are views sequentially illustrating another method for manufacturing a wiring board using the thin wiring member.

### DESCRIPTION OF EMBODIMENTS

Embodiments will now be described in detail with reference to the drawings. Hereinafter, the same or corresponding parts are denoted by the same reference numerals, and redundant description will be omitted. Unless otherwise specified, positional relationships such as up and down and right and left are based on the positional relationship illustrated in the drawings. Furthermore, the dimensional ratios in the drawings are not limited to the illustrated ratios.

The terms “left,” “right,” “front,” “back,” “up,” “down,” “upper,” “lower,” “first,” “second,” and the like used in this specification and claims are intended for illustrative purpose and do not necessarily signify that the illustrated relative positions are unchangeable. The term “layer” includes not only a structure having a shape formed all over a surface in plan view but also a structure having a shape formed on a part of a surface. The term “step” includes not only an independent step but also a step that cannot be clearly distinguished from other steps as long as the intended purpose of the step is achieved. In addition, a numerical range using “to” indicates a range including numerical values described before and after “to” as a minimum value and a maximum value. Furthermore, with regard to numerical ranges described in stages in this specification, an upper limit or a lower limit of a numerical range in a certain stage may be replaced with an upper limit or a lower limit of a numerical range in another stage.

### [Configuration of Thin Wiring Member]

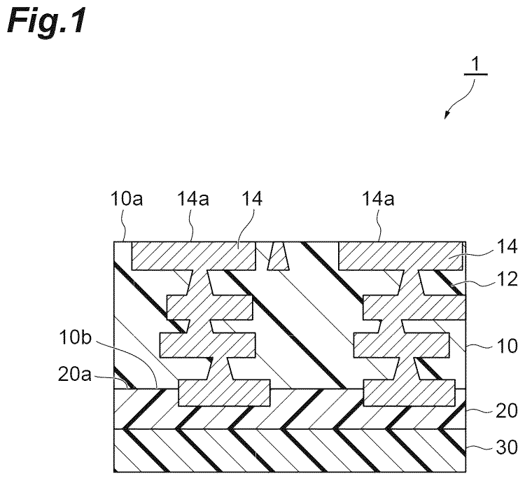

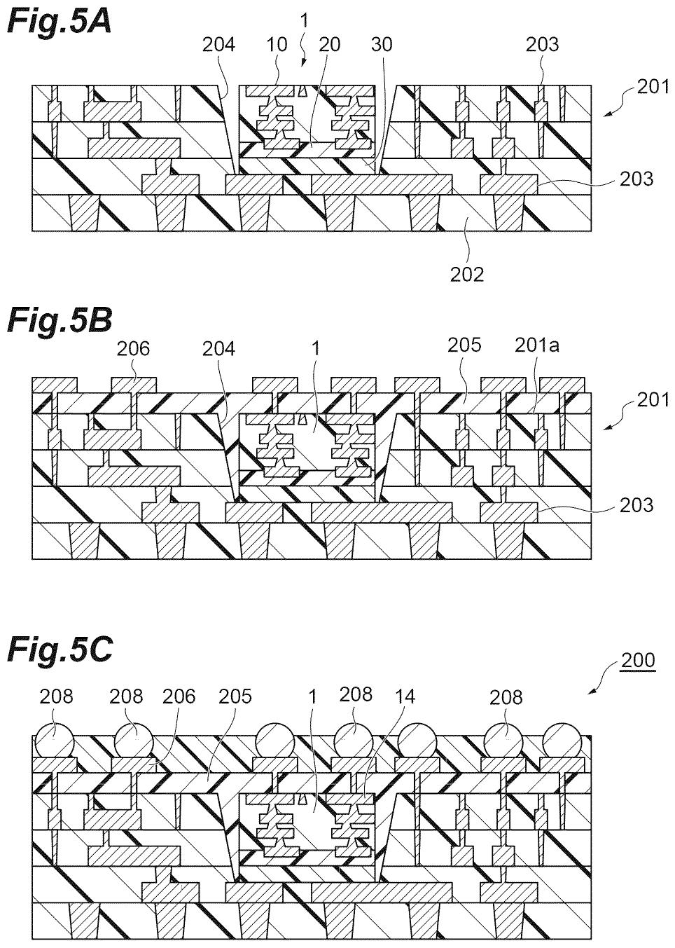

FIG. 1 is a cross-sectional view illustrating an example of a thin wiring member. As illustrated in FIG. 1, a thin wiring member 1 is, for example, a member used for forming a redistribution layer (RDL) of a wiring portion in a wiring board 200 to be described (see FIGS. 5A to 5C). Note that the thin wiring member 1 may be used for a wiring or connection of the wiring in a semiconductor device or the like. The thin wiring member 1 includes a fine wiring layer 10, a support layer 20, and an adhesive layer 30. The thin wiring member 1 is a minute wiring member that can be embedded in various kinds of wiring boards, semiconductor devices, and the like and may have, for example, a rectangular shape 50 mm long and 50 mm wide or a rectangular shape 20 mm long and 20 mm wide in plan view. The thin wiring member 1 includes the fine wiring layer 10 with a thickness of about 50 μm, having a total thickness as small as, for example, 30 μm to 1 mm. The fine wiring layer 10 has a thickness of, for example, 200 μm or less. Due to such a thickness, the thin wiring member 1 is prone to curl and difficult to handle.

As for the fine wiring layer 10, the fine wiring layer is formed by providing an insulating layer 12 (insulating portion) with a copper wiring 14 (wiring) that has a three-dimensional wiring structure. The copper wiring 14 has a fine line width of, for example, 0.5 to 5 μm. The copper wiring 14 preferably has a fine line width of 0.7 to 4 μm, and more preferably, a fine line width of 1 to 3 μm. A connection end 14a of the copper wiring 14 is exposed to the outside from a first surface 10a of the fine wiring layer 10. The connection end 14a of the copper wiring 14 is electrically and mechanically connected to a connection terminal. A second surface 10b of the fine wiring layer 10 is bonded and fixed to a first surface 20a of the support layer 20. As described later, the copper wiring 14 forms a three-dimensional wiring layer by sequentially stacking wiring layers from the second surface 10b toward the first surface 10a.

The insulating layer 12 is formed by stacking a plurality of layers. Each layer may have a thickness of, for example, 10 μm or less or 5 μm or less in terms of forming a fine via and groove. The insulating layer 12 is present around the copper wiring 14, filling the periphery of the copper wiring 14. In terms of electrical reliability, each layer in the insulating layer 12 may have a thickness of 1 μm or more. The insulating layer 12 as a whole may have a thickness of 10 to 200 μm or 10 to 100 μm. In terms of preventing a warp, the insulating layer 12 may have a coefficient of thermal expansion (after curing) of, for example, 80 ppm/° C. or less. In terms of preventing detachment or cracks in a reflow step and a heat cycle test, the insulating layer 12 may have a coefficient of thermal expansion (after curing) of, for example, 70 ppm/° C. or less. On the other hand, in terms of improving stress relaxation characteristics to form a fine via or groove, the insulating layer 12 may have a coefficient of linear expansion (after curing) of 20 ppm/° C. or more. Note that the insulating layer 12 may be equal to the support layer 20 in coefficient of linear expansion or may be smaller or larger than the support layer 20 in coefficient of linear expansion.

This insulating layer 12 is formed of a material such as polyimide resin, maleimide resin, epoxy resin, phenoxy resin, polybenzoxazole resin, acrylic resin, and acrylate resin. The insulating layer 12 may also contain a filler, and the filler to be contained may have an average particle size of 500 nm or less in terms of forming a fine part. The filler may be contained in the insulating layer 12 in such a manner that the filler content relative to the total insulating materials becomes less than 1 mass %. The insulating layer 12 does not necessarily contain a filler. Note that the insulating layer 12 is formed of the materials recited above and is formed as an adhesive and elastic layer having an unstable shape.

The support layer 20 is a layer for supporting the fine wiring layer 10 including the insulating layer 12 which is an unstable member and is formed of a material harder than a resin composition of the insulating layer 12 or a cured product of the resin composition. More specifically, the support layer 20 is formed of a material having a flexural modulus of 3 GPa or more (or a flexural strength of 700 MPa or more). The support layer 20 may be thinner than the fine wiring layer 10 or may be thicker than the fine wiring layer 10. The support layer 20 may have a thickness, for example, 25 to 3000% of the thickness of the fine wiring layer 10. The support layer 20 may be formed of a resin molded body filled with a filler, and the filling rate of the filler may be 50 to 55 mass % or 80 mass % or more. The filler to be filled may have a cut size of 20 μm or more. Furthermore, the support layer 20 may be a resin sheet having a glass cloth or may be a resin sheet having a hard layer (layer containing silicon, carbon, and copper) on the surface. The support layer 20 may have a coefficient of thermal expansion of 5 to 50 ppm/° C. Having such a coefficient of thermal expansion, the support layer 20 is prevented from being warped or the like.

More specifically, the support layer 20 may be formed of a thermosetting resin layer containing an inorganic filler. The thermosetting resin layer forming the support layer 20 may contain the inorganic filler in an amount of 40 to 90 mass %. The inorganic filler may have an average particle size of, for example, 0.05 μm or more. The average particle size herein is, for example, a value calculated by SEM. The thermosetting resin layer is a layer formed of a thermosetting resin composition containing a thermosetting resin and an inorganic filler. The thermosetting resin contained in the thermosetting resin composition may be one or more selected from the group consisting of maleimide resins having one or more N-substituted maleimide groups and derivatives thereof. One or more selected from the group consisting of maleimide resins having one or more N-substituted maleimide groups and derivatives thereof may be resins including a structure derived from a maleimide resin having two or more N-substituted maleimide groups and a structure derived from a silicone compound having a primary amino group.

The support layer 20 may further include a second thermosetting resin layer containing a rubber component in addition to the thermosetting resin layer. The second thermosetting resin layer is a layer formed of a second thermosetting resin composition containing a thermosetting resin and a rubber component. The thermosetting resin contained in the second thermosetting resin composition may be epoxy resin. The second thermosetting resin composition may further contain a phenol resin-based curing agent. The rubber component may be crosslinked rubber particles. The second thermosetting resin layer may contain an inorganic filler in an amount of 0 to 20 mass % or 0 to 5 mass %.

The adhesive layer 30 is a layer for attaching the thin wiring member 1 to a predetermined place such as a wiring board. The adhesive layer 30 is formed of epoxy resin or the like and includes, for example, a mixed resin of epoxy resin and acrylic rubber and also a filler. The adhesive layer 30 has a thickness of, for example, 5 to 40 μm. The adhesive layer 30 is formed of, for example, a die attach film (DAF). This adhesive layer may be formed on and integrated with a dicing tape having a sticky layer. The sticky layer may contain, for example, an ultraviolet curable resin.

### [Method for Manufacturing Thin Wiring Member]

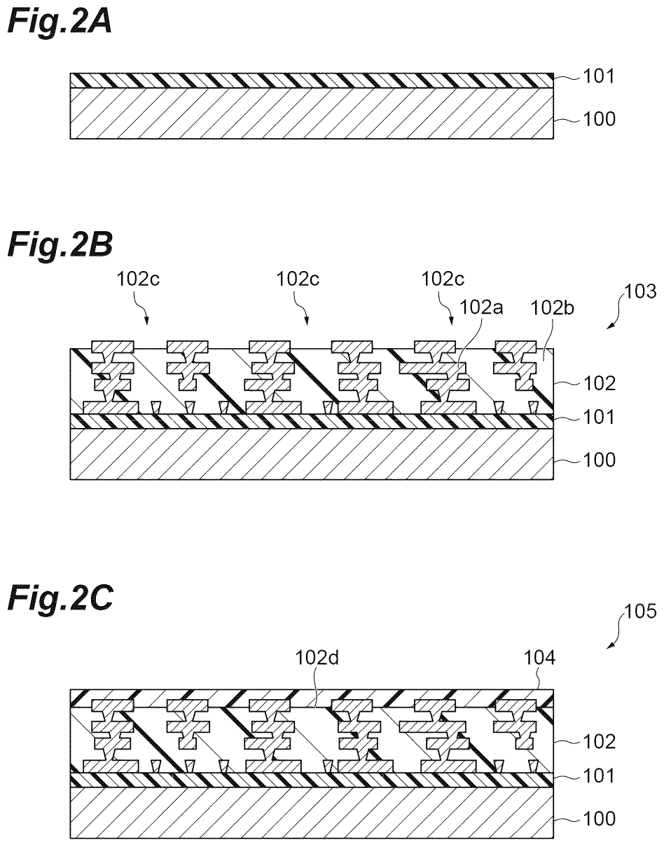

Next, a method for manufacturing the thin wiring member 1 will be described with reference to FIGS. 2A to 2C to FIGS. 4A to 4C. FIGS. 2A to 2C to FIGS. 4A to 4C are views sequentially illustrating the method for manufacturing the thin wiring member illustrated in FIG. 1. As illustrated in FIG. 2A, first, a glass carrier 100 (first carrier) is prepared. The glass carrier 100 is, for example, a carrier board having a thickness of 0.7 mm and has flatness with arithmetic average roughness of 50 nm or less. The glass carrier 100 is shaped into, for example, a wafer or a panel and may be, but not particularly limited to, a circular wafer having a diameter of 200 mm, 300 mm, or 450 mm or a rectangular panel having a side of 200 to 700 mm or less. A temporary fixing material 101 is put on the glass carrier 100 and bonded thereto. The temporary fixing material 101 is a resin layer for temporarily fixing an object on the glass carrier 100 and allows the temporarily fixed object to be detached by heating or a laser in a later step.

Next, a fine wiring layer 102 corresponding to the fine wiring layer 10 is formed. A method for forming the fine wiring layer 102 may be, but not particularly limited to, a semi-additive process (SAP) or a trench method. If a seed layer is to be formed, a method for forming the seed layer is not particularly limited as long as a metal layer is formed on the surface layer of the glass carrier 100 (temporary fixing material 101), and electroless plating or sputtering is employable.

In an example of the method for forming the fine wiring layer 102, first, a metal layer (seed layer) is formed on the temporary fixing material 101. The electroless plating for forming the metal layer is not particularly limited, but desmear or plasma may be employed to roughen the resin surface of the temporary fixing material 101, thereby forming the metal layer on the roughened surface. To form a high-yield fine wiring, it is preferable to employ a method involving irradiation of the resin surface with ultraviolet rays of 200 nm or less to prevent the resin surface from being rough and to improve surface energy of the resin surface, thereby forming the metal layer. As a method for irradiating with ultraviolet rays of 200 nm or less, for example, a low-pressure mercury lamp is employable. As a method for preventing the surface from being rough, the metal layer can be formed by sputtering. The seed layer can be easily removed by preventing the resin surface form being rough. The metal layer to be formed may have a thickness of 200 nm or less in terms of improving the yield at the time of fine wiring formation.

Next, a resist pattern is formed on the metal layer formed on the temporary fixing material 101. In this resist pattern, a groove part has a space width of, for example, 0.5 to 5 μm. A resist used for the resist pattern may be either a liquid resist or a film resist. The resist pattern can be formed by exposure using a stepper exposure machine and development using an alkaline aqueous solution.

As a method for forming a via or a groove in the resist pattern, laser ablation, photolithography, or imprinting is employable. In terms of fineness and cost, a photolithography process is employed. In this case, a photosensitive resin material is employable as an insulating material. As a method for exposing the photosensitive resin material, a known method is employable such as projection exposure method, contact exposure method, and direct imaging exposure method. As a method for development, an alkaline aqueous solution is employable such as sodium carbonate and TMAH. After forming the via and groove, the insulating layer may be further heated and cured. The heating may be performed at a temperature of 100 to 200° C. for 30 minutes to 3 hours.

Next, a copper wiring part is formed on the metal layer and in the groove of the resist pattern by electrolytic plating. In terms of improving the yield at the time of fine wiring formation, the metal layer may have a thickness of 10 μm or less. If the resist pattern has a space width of 0.5 to 5 μm, the line width of the copper wiring part in the resist pattern formed by electrolytic plating is also 0.5 to 5 μm. After the copper wiring part is formed, the resist pattern is detached and the metal layer is removed. The resist pattern is detached by a known method. The metal layer is removed using a commercially available etching solution.

Repeating the formation of a wiring layer forms a wiring body 103 having the fine wiring layer 102 disposed on the temporary fixing material 101 as illustrated in FIG. 2B. In FIG. 2B, four wiring layers 102a are stacked, but the present invention is not limited to this example. An insulating part 102b other than the wiring of the fine wiring layer 102 is formed of a resin material such as polyimide resin, maleimide resin, epoxy resin, phenoxy resin, polybenzoxazole resin, acrylic resin, and acrylate resin. The insulating part 102b is present around the wiring layers 102a, filling the periphery of the wiring layers 102a. Such an insulating part 102b has adhesiveness and elasticity and has an unstable shape. In addition, the fine wiring layer 102 is provided with a plurality of fine wiring layers 102c (wiring portions) respectively corresponding to fine wiring layers 10 of a plurality of thin wiring members 1. Each fine wiring layer 102c includes a part of the wiring layers 102a and a part of the insulating part 102b. After the fine wiring layer 102 is formed, chemical mechanical polishing (CMP) may be performed in order to planarize unevenness of the surface.

Next, as illustrated in FIG. 2C, a support layer 104 corresponding to the support layer 20 is formed on the fine wiring layer 102. The support layer 104 is a film-like member bonded to an upper surface 102d of the fine wiring layer 102, for example, by lamination. The support layer 104 is formed of a material harder than the resin part 102b of the fine wiring layer 102 and supports the fine wiring layer 102. Examples of the support layer 104 include a resin molded body filled with about 50 to 55 mass % of a filler, a resin sheet having a glass cloth, and a resin sheet having a hard layer on the surface. In terms of self-sharpening of a blade, the support layer 104 is preferably a resin molded body containing a filler at a filling rate of 80% or more. In this case, it is more preferable that the filler has a cut size of 20 μm or more. Alternatively, in terms of self-sharpening of the blade, the support layer 104 is preferably a resin sheet having a hard layer containing silicon, carbon, copper, or the like on the surface. The support layer 104 is preferably formed of a material having a low coefficient of thermal expansion of, for example, 50 ppm/° C. or less. In addition, the outer surface (surface on the side to be diced) of the support layer 104 is preferably smooth and have arithmetic average roughness Ra of, for example, 50 nm or less.

The support layer 104 is formed of a material harder than a resin composition of the insulating part 102b of the fine wiring layer 102 or a cured product of the resin composition. More specifically, the support layer 104 is formed of a material having a flexural modulus of 3 GPa or more (or a flexural strength of 700 MPa or more). The support layer 104 may be thinner than the fine wiring layer 102 and have a thickness, for example, 20 to 80% of the thickness of the fine wiring layer 102. Alternatively, the support layer 104 may have a thickness 25 to 3000% of the thickness of the fine wiring layer 102.

An example of the support layer 104 includes the thermosetting resin layer containing an inorganic filler. The thermosetting resin layer contains the inorganic filler in an amount of, for example, 40 to 90 mass %.

The thermosetting resin layer forming the support layer 104 is a thermosetting resin layer containing an inorganic filler. The thermosetting resin layer forms a cured product layer that is fused and cured by heating. The thermosetting resin layer contains the inorganic filler in an amount of 40 to 90 mass %. If the amount of the inorganic filler contained in the thermosetting resin layer is equal to or more than the aforementioned lower limit, it is possible to obtain excellent low-temperature expansion and heat resistance. If the amount of the inorganic filler contained in the thermosetting resin layer is equal to or less than the aforementioned upper limit, it is possible to obtain excellent moldability and conductor adhesiveness. From similar perspectives, the thermosetting resin layer preferably contains the inorganic filler in an amount of, but not particularly limited to, 55 to 80 mass %, more preferably, 60 to 75 mass %, and still more preferably, 65 to 70 mass %. The thickness of the thermosetting resin layer is preferably, but not particularly limited to, 4 to 100 μm, more preferably, 6 to 60 μm, and still more preferably, 8 to 40 μm. The thermosetting resin layer may have a thickness of 50 μm to 1200 μm.

Examples of a thermosetting resin contained in the thermosetting resin layer include epoxy resin, phenol resin, maleimide resin, cyanate resin, isocyanate resin, benzoxazine resin, oxetane resin, amino resin, unsaturated polyester resin, allyl resin, dicyclopentadiene resin, silicone resin, triazine resin, and melamine resin. In terms of heat resistance, maleimide resin, epoxy resin, and cyanate resin among these examples are preferable, maleimide resin and epoxy resin are more preferable, and maleimide resin is still more preferable. These examples of the thermosetting resin may be used independently, or two or more of them may be used in combination.

The maleimide resin is preferably one or more selected from the group consisting of maleimide resins having one or more N-substituted maleimide groups and derivatives thereof. In other words, the thermosetting resin layer is preferably a layer formed of a thermosetting resin composition containing a thermosetting resin and an inorganic filler, and the thermosetting resin contained in the thermosetting resin composition is preferably one or more selected from the group consisting of maleimide resins having one or more N-substituted maleimide groups and derivatives thereof. One or more selected from the group consisting of maleimide resins having one or more N-substituted maleimide groups and derivatives thereof are preferably a maleimide resins having two or more N-substituted maleimide groups, or a resin including a structure derived from a maleimide resin having two or more N-substituted maleimide groups and a structure derived from a silicone compound having a primary amino group. In terms of heat resistance and low-temperature expansion, a silicone-modified maleimide resin is more preferable. In this embodiment, the silicone-modified maleimide resin is an aspect of the maleimide resin.

Examples of the inorganic filler contained in the thermosetting resin layer constituting the support layer 104 include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, and silicon carbide. In terms of low-temperature expansion, heat resistance, and flame retardancy, silica, alumina, mica, and talc among these examples are preferable, silica and alumina are more preferable, and silica is still more preferable.

Examples of the silica include precipitated silica which is produced by a wet method and has a high moisture content and dried silica which is produced by a dry method and hardly contains bound water or the like. Examples of the dried silica include crushed silica, fumed silica, and fused silica depending on manufacturing methods.

In terms of dispersibility and fine wiring properties of the inorganic filler, the average particle size of the inorganic filler is, but not particularly limited to, 0.01 to 20 μm, preferably, 0.05 to 20 μm, more preferably, 0.1 to 10 μm, still more preferably, 0.2 to 1 μm, and particularly preferably, 0.3 to 0.8 μm. In this specification, the average particle size refers to a particle diameter at a point corresponding to a 50% volume in a cumulative frequency distribution curve of particle diameters, assuming that the total volume of particles is 100%. The average particle size of the inorganic filler can be measured, for example, with a device for measuring particle size distribution using laser diffraction techniques. Examples of the shape of the inorganic filler include a spherical shape and a crushed shape, and it is preferable that the inorganic filler has a spherical shape.

The thermosetting resin composition may employ a coupling agent for the purpose of improving dispersibility of the inorganic filler and adhesion to an organic component. Examples of the coupling agent include a silane coupling agent and a titanate coupling agent. Among these examples, a silane coupling agent is preferable. Examples of the silane coupling agent include an aminosilane coupling agent, a vinylsilane coupling agent, and an epoxysilane coupling agent.

If a coupling agent is used for the thermosetting resin composition, a method for treating the surface of the inorganic filler may be integral blending in which the inorganic filler is blended in the resin composition, followed by adding the coupling agent. However, it is preferable to treat the surface of the inorganic filler in advance by a dry or wet method. For the purpose of improving dispersibility, the inorganic filler may be dispersed in an organic solvent in advance and made into slurry, and then, mixed with other components.

The support layer 104 may further include the second thermosetting resin layer containing a rubber component as an optional layer. The second thermosetting resin layer contains an inorganic filler in an amount of, for example, 0 to 20 mass %. The second thermosetting resin layer prevents cracks in the resin layer. In this specification, the “rubber component” refers to a crosslinked elastomer or a crosslinkable elastomer. The rubber component contained in the second thermosetting resin layer may be reacted with another component. The second thermosetting resin layer contains the inorganic filler in an amount of 0 to 20 mass %. If the amount of the inorganic filler contained in the second thermosetting resin layer is equal to or less than the aforementioned upper limit, it is possible to sufficiently prevent cracks in the resin layer.

From a similar perspective, the second thermosetting resin layer preferably contains the inorganic filler in an amount of, but not particularly limited to, 0 to 10 mass %, more preferably, 0 to 5 mass %, and still more preferably, 0 to 1 mass %. The inorganic filler in the second thermosetting resin layer may employ the same inorganic filler as the inorganic filler in the thermosetting resin layer.

The second thermosetting resin layer is a layer formed of a second thermosetting resin composition containing a thermosetting resin and a rubber component. Examples of the thermosetting resin used for the second thermosetting resin layer include epoxy resin, phenol resin, maleimide resin, cyanate resin, isocyanate resin, benzoxazine resin, oxetane resin, amino resin, unsaturated polyester resin, allyl resin, dicyclopentadiene resin, silicone resin, triazine resin, and melamine resin. In terms of heat resistance, maleimide resin, epoxy resin, and cyanate resin among these examples are preferable, maleimide resin and epoxy resin are more preferable, and epoxy resin is still more preferable. These examples of the thermosetting resin (a) may be used independently, or two or more of them may be used in combination.

Examples of the rubber component used in the second thermosetting resin layer include crosslinked rubber particles and liquid rubber. Among these examples, crosslinked rubber particles are preferable in terms of preventing cracks in the resin layer. Examples of the crosslinked rubber particles include butadiene rubber particles, isoprene rubber particles, chloroprene rubber particles, styrene rubber particles, acrylic rubber particles, silicone rubber particles, natural rubber particles, styrene-butadiene rubber particles, acrylonitrile butadiene rubber particles, carboxylic acid-modified acrylonitrile butadiene rubber particles, and core-shell rubber particles. Among these examples, acrylonitrile butadiene rubber particles and carboxylic acid-modified acrylonitrile butadiene rubber particles are preferable, and carboxylic acid-modified acrylonitrile butadiene rubber particles are more preferable. These examples of the rubber component (b) may be used independently, or two or more of them may be used in combination.

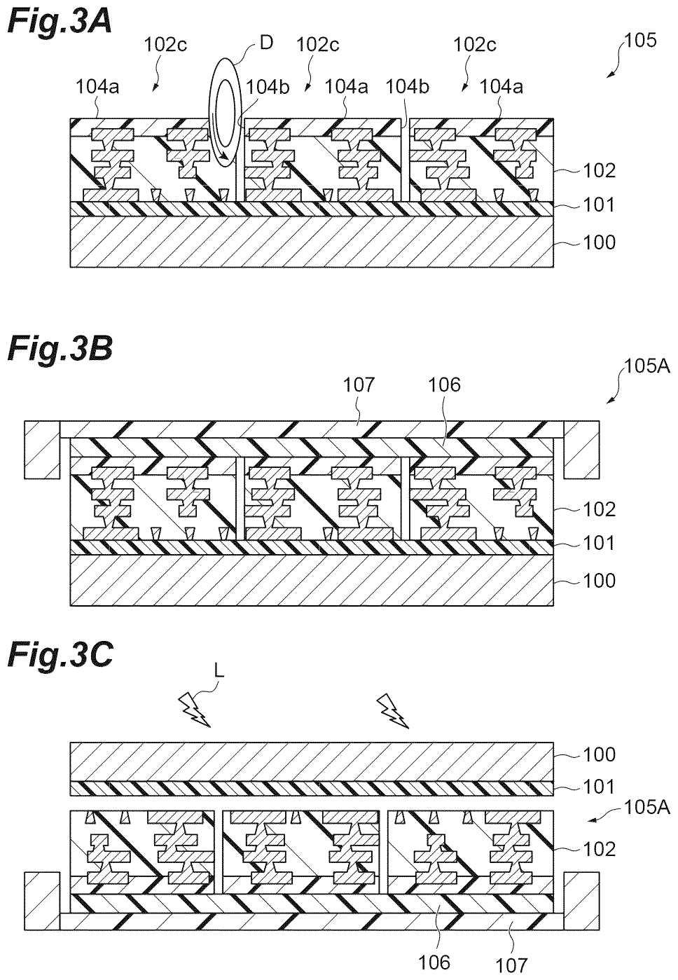

Next, as illustrated in FIG. 3A, a wiring body 105 including the fine wiring layer 102 and the support layer 104 is singulated in such a manner that each singulated wiring body includes at least one fine wiring layer 102c among the plurality of fine wiring layers 102c. In this step of singulating, the fine wiring layer 102 is cut from the support layer 104 side by dicing with a dicer using a blade D, thereby being divided into small pieces. The singulation of the support layer 104 forms a plurality of support layers 104a. Furthermore, a cutting region 104b is formed between the support layers 104a. During the dicing, note that the temporary fixing material 101 is not necessarily cut. Alternatively, a part of the temporary fixing material 101 may be cut.

Next, as illustrated in FIG. 3B, a wiring body 105A obtained by the dicing is bonded to a dicing tape 107 with an adhesive film 106 involved. After that, as illustrated in FIG. 3C, the temporary fixing material 101 is irradiated with a laser L, whereby the glass carrier 100 and the temporary fixing material 101 are detached from the wiring body 105A.

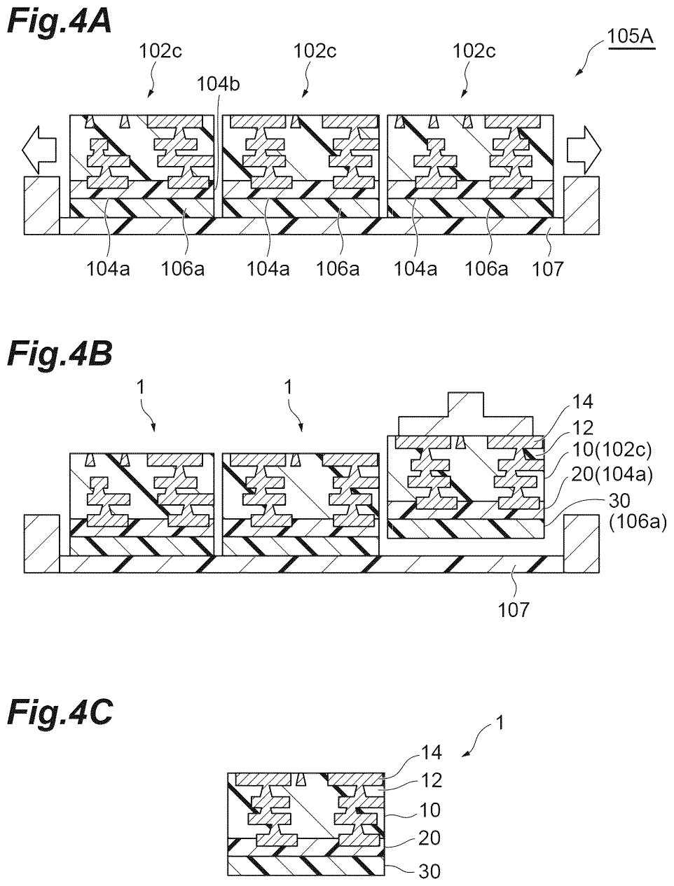

Next, as illustrated in FIG. 4A, the dicing tape 107 is expanded radially outward, and the adhesive film 106 is singulated in a similar manner to the wiring body 105 and divided into individual adhesive films 106a. Note that the adhesive film 106 may be singulated by expansion while being cooled. If the adhesive film 106 is singulated by expansion, a tearing force is transmitted to a film or the like around the adhesive film 106. However, in this manufacturing method, the hard support layers 104a are disposed on the adhesive film 106. For this reason, no force is transmitted to the fine wiring layers 102c, which has no influence on the dimensional accuracy of the singulated fine wiring layers 102c. In this manner, the adhesive film 106 is separated along the cutting region 104b of the support layer 104a, and a layer corresponding to the adhesive layer is formed. After that, as illustrated in FIG. 4B, each singulated thin wiring member 1 is picked up, thereby obtaining the thin wiring member 1 as illustrated in FIG. 4C.

### [Manufacturing Method for Wiring Board]

With reference to FIGS. 5A to 5C, hereinafter described is a method for manufacturing a wiring board using the thin wiring member 1. FIGS. 5A to 5C is a view sequentially illustrating a method for manufacturing a wiring board using the thin wiring member. In this method for manufacturing a wiring board, first, the thin wiring member 1 is prepared, and a board body 201 is prepared. As illustrated in FIG. 5A, the board body 201 is a board-shaped member formed by alternately stacking an insulating layer 202 and a wiring layer 203. The board body 201 is provided with an opening 204 where the thin wiring member 1 is to be placed. When the preparation of the thin wiring member 1 and the like is completed, the thin wiring member 1 is placed in the opening 204 of the board body 201. Note that the adhesive layer 30 of the thin wiring member 1 is bonded to the bottom surface of the opening 204.

Next, as illustrated in FIG. 5B, an insulating resin part 205 is formed on the remaining part of the opening 204 where the thin wiring member 1 is placed and on a surface 201a of the board body 201. The insulating resin part 205 may be formed using an insulating resin film or may be formed by applying and filling a liquid resin composition. In addition, the insulating resin part 205 is patterned to form a wiring 206. After that, as illustrated in FIG. 5C, a connection terminal 208 is prepared, and the copper wiring 14 of the thin wiring member 1 and the connection terminal 208 are electrically connected to each other. In this manner, a wiring board 200 is obtained.

In the method for manufacturing a thin wiring member according to this embodiment, the support layer 104 harder than the insulating part 102b of the fine wiring layer 102 is formed, and the wiring body 105 including the fine wiring layer 102 and the support layer 104 is singulated in such a manner that each singulated wiring body includes at least one fine wiring layer 102c. Accordingly, it is possible to perform singulation in a state where the fine wiring layer 102 having an unstable shape is supported by the hard support layer 104. Therefore, this manufacturing method enables accurate singulation of the thin wiring member 1 that has a small thickness and an unstable shape. If the fine wiring layer 102 is thin, an impact (for example, water pressure) during the singulation (for example, dicing) may turn the fine wiring layer 102 up. However, according to this manufacturing method, such a problem is prevented by the support layer 104 supporting the fine wiring layer 102. In this manufacturing method, the wiring body 105 is singulated in a state where the support layer 104 which is harder than other parts is bonded to the surface of the fine wiring layer 102, thereby reliably enabling singulation.

In the method for manufacturing a thin wiring member according to this embodiment, at the time of singulation, the wiring body 105 is singulated by dicing with the blade D from the support layer 104 toward the fine wiring layer 102. The dicing is performed from the hard support layer 104 side, and it is possible to accurately dice the fine wiring layer 102 which is cut subsequently to the support layer 104 and has an unstable shape, thereby enhancing the dicing performance.

In the method for manufacturing a thin wiring member according to this embodiment, at the time of singulation, the wiring body 105 is singulated by dicing with the blade D in a state where the fine wiring layer 102 is sandwiched between the glass carrier 100 and the support layer 104. In this case, the dicing is performed in a state where the fine wiring layer 102 having an unstable shape is sandwiched and fixed between the glass carrier 100 and the hard support layer 104 so as not to move, thereby enabling the dicing with higher accuracy.

The method for manufacturing a thin wiring member according to this embodiment may further include a step of bonding the singulated wiring body 105 to the adhesive film 106, a step of removing the glass carrier 100 from the wiring body 105 bonded to the adhesive film 106, and a step of expanding the adhesive film 106 to which the singulated wiring body 105 is bonded. In this manufacturing method, the adhesive film 106 is bonded to the support layer 104 of the wiring body 105 in the step of bonding, and the adhesive film 106 is separated along the cutting region 104b in the support layer 104 in the step of expanding. In this case, it is possible to prevent reduction of dimensional accuracy which is caused when the fine wiring layer 102 having an unstable shape is pulled by the separation of the adhesive film 106 at the time of expansion. Accordingly, this manufacturing method makes it possible to keep high dimensional accuracy of the thin wiring member.

In the method for manufacturing a thin wiring member according to this embodiment, the fine wiring layer 102 may have a thickness of 200 μm or less. In this case, the thin wiring member 1 can be reliably made thinner. Even with the fine wiring layer 10 having a thickness of 200 μm or less, the manufacturing method according to any one of the aforementioned descriptions enables accurate singulation of the wiring body that has the wiring layer having an unstable shape.

In the manufacturing method for a thin wiring member according to this embodiment, the support layer 104 may have a thickness 25 to 3000% or less of the thickness of the fine wiring layer 102. With the support layer 104 having a thickness 25% or more of the thickness of the fine wiring layer 102, the wiring layer that has an unstable shape is firmly supported by the support layer 104, which enables accurate singulation. With the support layer 104 having a thickness 3000% or less of the thickness of the fine wiring layer 102, it is possible to keep the thin wiring member thin without increasing the thickness.

In the method for manufacturing a thin wiring member according to this embodiment, the support layer 104 may be formed of a material having a flexural modulus of 3 GPa or more (or a flexural strength of 700 MPa or more). In this case, at the time of singulation, the fine wiring layer 102 having an unstable shape is reliably supported by the hard support layer 104. Accordingly, this manufacturing method enables accurate singulation.

In the method for manufacturing a thin wiring member according to this embodiment, the support layer 104 may include a thermosetting resin layer containing an inorganic filler. In this case, the inorganic filler enables the blade to exert its self-sharpening action. In this case, the thermosetting resin layer preferably contains the inorganic filler in an amount of 40 to 90 mass % or less. The inorganic filler preferably has an average particle size of 0.05 μm or more, and more preferably, 0.1 μm or more.

In the method for manufacturing a thin wiring member according to this embodiment, the glass carrier 100 may have arithmetic average roughness Ra of 50 nm or less. In this case, the wiring layer fabricated on the glass carrier 100 can be made fine with accuracy.

In the method for manufacturing a thin wiring member according to this embodiment, the fine wiring layer 102 may include a wiring having a line width of 5 μm or less. In this case, it is possible to obtain a thin wiring member having a fine wiring.

### [Another Method for Manufacturing Thin Wiring Member]

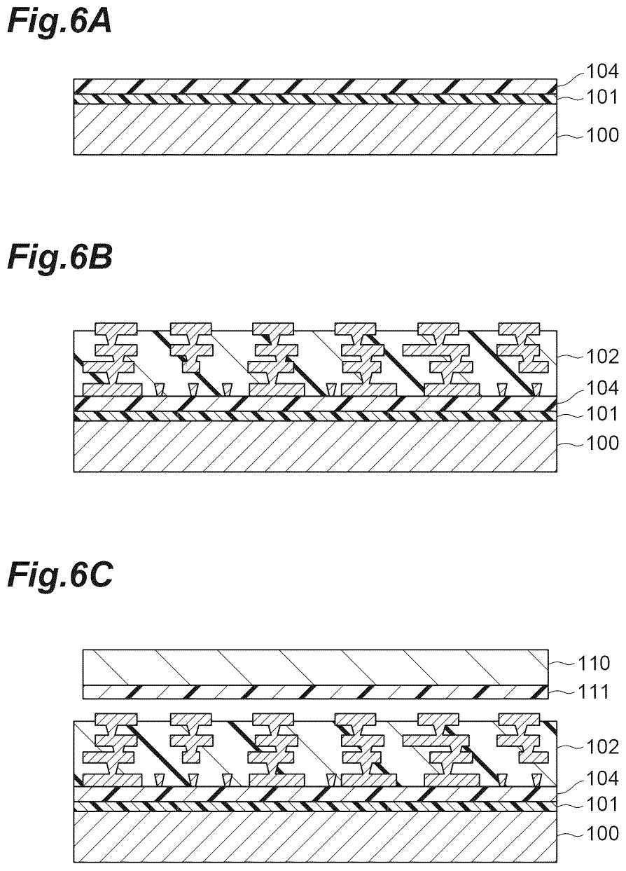

With reference to FIGS. 6A to 6C to FIGS. 8A to 8C, hereinafter described is another method for manufacturing the thin wiring member 1. FIGS. 6A to 6C to FIGS. 8A to 8C are views sequentially illustrating another method for manufacturing the thin wiring member illustrated in FIG. 1. Hereinafter mainly describe are differences from the aforementioned method for manufacturing a thin wiring member. The same parts or the same members will not be described.

As illustrated in FIG. 6A, first, the glass carrier 100 is prepared. Next, the temporary fixing material 101 is put on the glass carrier 100 and bonded thereto. In this manufacturing method, the support layer 104 is formed also on the temporary fixing material 101. The support layer 104 is a layer formed of a hard material as described above.

Next, as illustrated in FIG. 6B, the fine wiring layer 102 is fabricated on the support layer 104. The fine wiring layer 102 can be fabricated by the same process as the aforementioned method, for example, by a semi-additive process (SAP) or a trench method.

Next, as illustrated in FIG. 6C, another carrier 110 (second carrier) is put on the fine wiring layer 102 and bonded thereto. The carrier 110 may be provided with a sticky layer 111. The carrier 110 may be formed of glass similarly to the glass carrier 100 or may be formed of different materials.

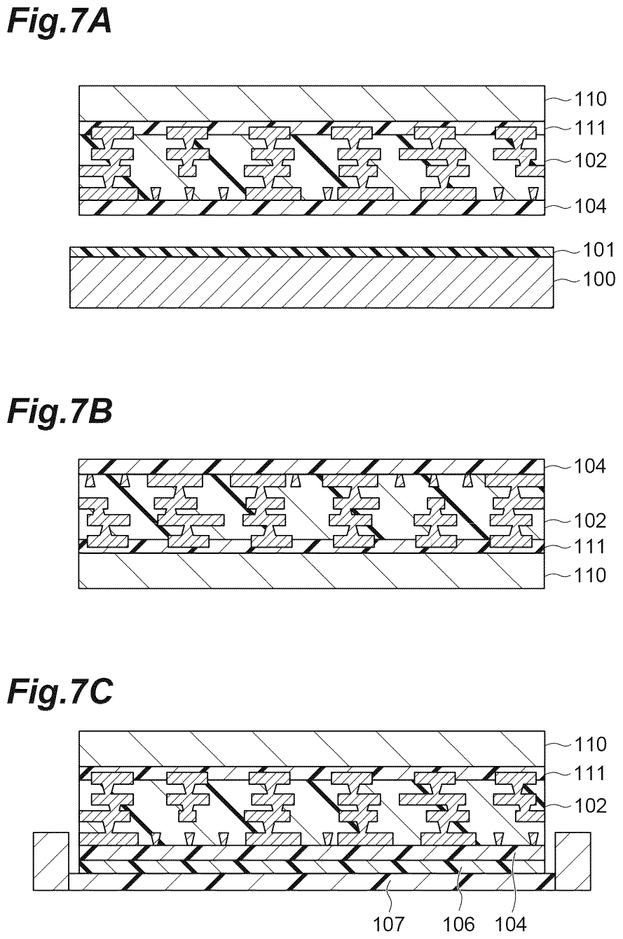

Next, after the carrier 110 is bonded to the fine wiring layer 102, as illustrated in FIG. 7A, the glass carrier 100 used for fabricating the fine wiring layer 102 is detached. As in the aforementioned manufacturing method, the glass carrier 100 is detached by detaching the temporary fixing material 101 by laser irradiation.

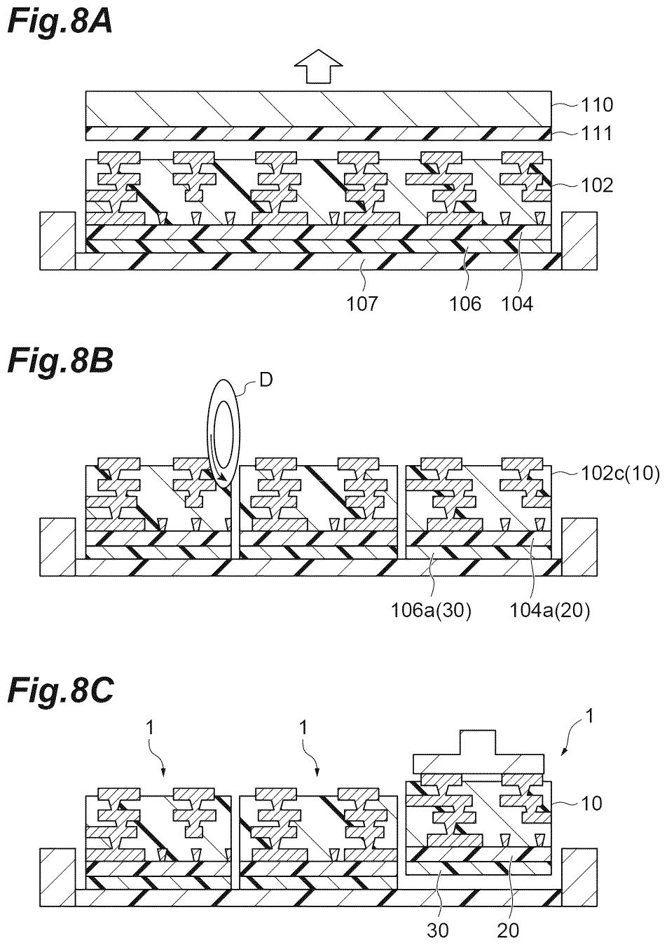

Next, after the glass carrier 100 is detached, the surface of the support layer 104 is wet etched as illustrated in FIG. 7B. Accordingly, components of the temporary fixing material attached to the support layer are removed. After that, as illustrated in FIG. 7C, the fine wiring layer 102 is bonded to the dicing tape 107 with the adhesive film 106 involved. Next, when the bonding of the fine wiring layer 102 to the dicing tape is completed, the carrier 110 is detached by a laser or the like as illustrated in FIG. 8A. As illustrated in FIG. 8B, the fine wiring layer 102 and the support layer 104 are singulated from the fine wiring layer 102 toward the support layer 104 by dicing using the blade D of the dicer. During the dicing, the adhesive film 106 is also singulated. Through such dicing, as illustrated in FIGS. 8B and 8C, the thin wiring members 1 each including the fine wiring layer 102c, the support layer 104a, and the adhesive film 106a are formed.

In this method for manufacturing a thin wiring member according to this embodiment, similarly to the aforementioned manufacturing method, the support layer 104 harder than the insulating part 102b of the fine wiring layer 102 is formed, and the wiring body including the fine wiring layer 102 and the support layer 104 is singulated in such a manner that each singulated wiring body includes at least one fine wiring layer 102c. Accordingly, it is possible to perform singulation in a state where the fine wiring layer 102 having an unstable shape is supported by the hard support layer 104. Therefore, this manufacturing method enables accurate singulation of the thin wiring member 1 that has a small thickness and an unstable shape. If the fine wiring layer 102 is thin, an impact (for example, water pressure) during the singulation (for example, dicing) may turn the fine wiring layer 102 up. However, according to this manufacturing method, such a problem is prevented by the support layer 104 supporting the fine wiring layer 102. Particularly, the support layer 104 supports the lower side of the fine wiring layer 102, so that the fine wiring layer 102 is prevented from turning up in a preferred manner. In this manufacturing method, the wiring body is singulated in a state where the hard support layer 104 is bonded to the surface of the fine wiring layer 102, and this configuration reliably prevents the fine wiring layer 102 from turning up.

In this method for manufacturing a thin wiring member according to this embodiment, at the time of singulation, the wiring body is singulated by dicing with the blade D from the fine wiring layer 102 toward the support layer 104. In this case, although the dicing is performed from the fine wiring layer 102, the fine wiring layer 102 is firmly supported by the hard support layer 104 on the opposite surface, thereby enabling the dicing in a state where the fine wiring layer 102 is fixed to some extent. Accordingly, this manufacturing method enables accurate dicing of a wiring member that has a small thickness and an unstable shape.

The method for manufacturing a thin wiring member according to this embodiment also includes a step of bonding the carrier 110 to a surface of the fine wiring layer 102 opposite to a surface to which the support layer 104 is bonded, a step of removing the glass carrier 100 after bonding the carrier 110, and a step of bonding the wiring body having the carrier 110 bonded thereto to the adhesive film 106. In the step of singulating, the fine wiring layer 102, the support layer 104, and the adhesive film 106 may be singulated by dicing after being bonded to the adhesive film 106. In this case, it is possible to remove the glass carrier 100 to which the support layer 104 is bonded, thereby enabling removal of the temporary fixing material attached to the support layer by etching or the like. In addition, due to the dicing performed up to the adhesive film 106, it is possible to prevent reduction of dimensional accuracy of the fine wiring layer 102 accompanied by the separation of the adhesive film 106 at the time of expansion of the adhesive film 106.

The method for manufacturing a thin wiring member according to this embodiment further includes a step of removing the carrier 110. The fine wiring layer 102, the support layer 104, and the adhesive film 106 are singulated in the step of singulating by dicing after the carrier 110 is removed. In this manner, there is no need to dice the carrier 110, and the material of the carrier 110 can be selected more freely. The non-necessity of dicing the carrier 110 increases the speed of dicing, which enhances the efficiency of fabrication. It is clear that this manufacturing method according to this embodiment similarly exhibits other functions and effects obtained in the aforementioned manufacturing method, thus the functions and effects will not be described herein.

### [Yet Another Method for Manufacturing Thin Wiring Member]

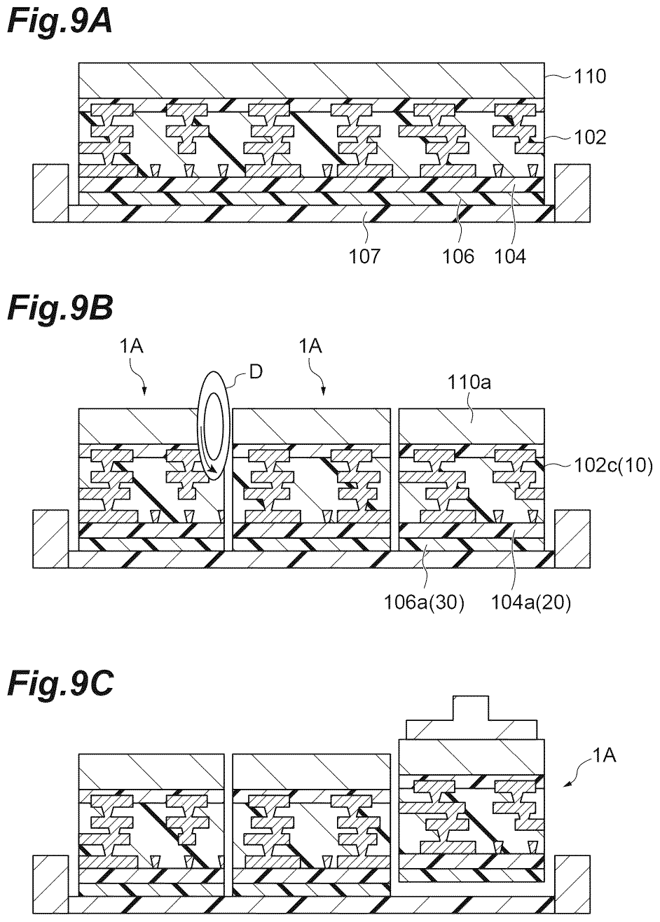

Next, yet another method for manufacturing the thin wiring member 1 will be described with reference to FIGS. 9A to 9C. FIGS. 9A to 9C are views sequentially illustrating yet another method for manufacturing the thin wiring member illustrated in FIG. 1. Hereinafter mainly describe are differences from the aforementioned method for manufacturing a thin wiring member and the other method for manufacturing a thin wiring member. The same parts or the same members will not be described.

In this manufacturing method, first, the steps illustrated in FIG. 6A to FIG. 7C of the manufacturing method are performed in a similar manner. FIG. 9A corresponds to FIG. 7C. In this manufacturing method, as illustrated in FIG. 9A, when the adhesive film 106 is bonded to the fine wiring layer 102 to which the carrier 110 is bonded, the wiring body is singulated by dicing with the dicer without detaching the carrier 110 as illustrated in FIG. 9B. Accordingly, as illustrated in FIGS. 9B and 9C, thin wiring members 1A each including the fine wiring layer 102c (10), the support layer 104a (20), the adhesive film 106a (30), and a carrier 110a are formed.

In this manner, in the method for manufacturing a thin wiring member according to this embodiment, the carrier 110, the fine wiring layer 102, the support layer 104, and the adhesive film 106 are singulated by dicing at the time of singulation. In this case, the dicing is performed in a state where the fine wiring layer 102 having an unstable shape is sandwiched and fixed between the hard carrier 110 and the hard support layer 104 so as not to move, thereby enabling the dicing with accuracy. It is clear that this manufacturing method according to this embodiment similarly exhibits other functions and effects obtained in the aforementioned manufacturing method and the other manufacturing method, thus the functions and effects will not be described herein.

### [Another Method for Manufacturing Wiring Board]

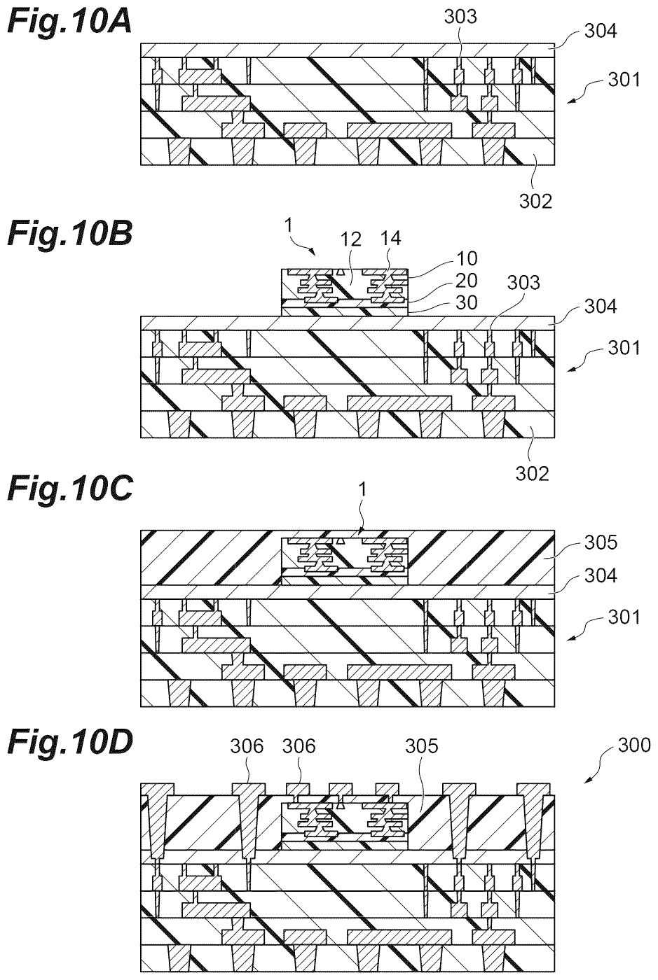

With reference to FIGS. 10A to 10D, hereinafter described is another method for manufacturing a wiring board using the thin wiring member 1. FIGS. 10A to 10D are views sequentially illustrating another method for manufacturing a wiring board using the thin wiring member. In this method for manufacturing a wiring board, first, the thin wiring member 1 is prepared, and a board body 301 is prepared. As illustrated in FIG. 10A, the board body 301 is a member formed by alternately stacking an insulating layer 302 and a wiring layer 303. The board body 301 is provided with a placement layer 304 where the thin wiring member 1 is to be placed.

When the preparation of the thin wiring member 1 and the like is completed, as illustrated in FIG. 10B, the thin wiring member 1 is placed on the placement layer 304 of the board body 301. At this time, the adhesive layer 30 of the thin wiring member 1 is bonded to the placement layer 304.

Next, as illustrated in FIG. 10C, an insulating resin part 305 is formed on the placement layer 304 of the board body 301 where the thin wiring member 1 is placed. In addition, the insulating resin part 305 is patterned to form a wiring 306. After that, a connection terminal may also be prepared. In this manner, a wiring board 300 is obtained.

Although a method for manufacturing a thin wiring member, a thin wiring member, and a method for manufacturing a wiring board according to embodiments of the present disclosure have been described, the present disclosure is not limited to the aforementioned embodiment and can be appropriately changed without departing from the gist of the present disclosure. For example, in the embodiment described above, the fine wiring layer 102 is singulated by dicing with a dicer (blade D), but the fine wiring layer 102 may be singulated by a laser or the like. In addition, a method for dividing the adhesive film 106 to which the wiring body after singulation is bonded is not limited to the expansion. A predetermined portion of the adhesive film 106 may be burned off by a laser or divided with a blade.

### REFERENCE SIGNS LIST

1, 1A Thin wiring member
10 Fine wiring layer
20 Support layer
30 Adhesive layer
100 Glass carrier (first carrier)
102 Fine wiring layer
102b Insulating part (insulating portion)
102c Fine wiring layer (wiring portion)
104 Support layer
105, 105A Wiring body
106 Adhesive film
110 Carrier (second carrier)
201, 301 Board body (board)
206, 208, 306 Connection terminal
200, 300 Wiring board

1. A method for manufacturing a plurality of thin wiring members, the method comprising:
preparing a first carrier;
fabricating a wiring layer on the first carrier, the wiring layer including a plurality of wiring portions corresponding to the plurality of thin wiring members and an insulating portion present around the plurality of wiring portions;
forming a support layer harder than the insulating portion of the wiring layer; and
singulating a wiring body including the wiring layer and the support layer such that each singulated wiring body includes at least one wiring portion of the plurality of wiring portions.

2. The method for manufacturing a plurality of thin wiring members according to claim 1,
wherein the wiring body is singulated by dicing with a blade from the support layer toward the wiring layer in the singulating.

3. The method for manufacturing a plurality of thin wiring members according to claim 2,
wherein the wiring body is singulated by dicing in a state where the wiring layer is sandwiched between the first carrier and the support layer in the singulating.

4. The method for manufacturing a plurality of thin wiring members according to claim 2, the method further comprising:
bonding the singulated wiring body to an adhesive film;
removing the first carrier from the wiring body after bonding to the adhesive film; and
dividing the adhesive film to which the singulated wiring body is bonded,
wherein the adhesive film is bonded to the support layer of the wiring body in the bonding, and
the adhesive film is separated along a cutting region in the support layer in the dividing.

5. The method for manufacturing a plurality of thin wiring members according to claim 1,
wherein the support layer is formed on the first carrier in the forming of the support layer, and
the wiring layer is fabricated on the support layer in the fabricating of the wiring layer.

6. The method for manufacturing a plurality of thin wiring members according to claim 5,
wherein the wiring body is singulated by dicing with a blade from the wiring layer toward the support layer in the singulating.

7. The method for manufacturing a plurality of thin wiring members according to claim 6, the method further comprising:
bonding a second carrier to a surface of the wiring layer opposite to a surface to which the support layer is bonded;
removing the first carrier after bonding the second carrier; and
bonding, to an adhesive film, the wiring body to which the second carrier is bonded,
wherein the wiring layer, the support layer, and the adhesive film are singulated by dicing in the singulating after being bonded to the adhesive film.

8. The method for manufacturing a plurality of thin wiring members according to claim 7, the method further comprising:
removing the second carrier,
wherein the wiring layer, the support layer, and the adhesive film are singulated by dicing in the singulating after the second carrier is removed.

9. The method for manufacturing a plurality of thin wiring members according to claim 7,
wherein the second carrier, the wiring layer, the support layer, and the adhesive film are singulated by dicing in the singulating.

10. The method for manufacturing a plurality of thin wiring members according to claim 1,
wherein the wiring layer has a thickness of 200 μm or less.

11. The method for manufacturing a plurality of thin wiring members according to claim 1,
wherein the support layer has a thickness 25% or more and 3000% or less of a thickness of the wiring layer.

12. The method for manufacturing a plurality of thin wiring members according to claim 1,
wherein the support layer is formed of a material having a flexural modulus of 3 GPa or more.

13. The method for manufacturing a plurality of thin wiring members according to claim 1,
wherein the support layer includes a thermosetting resin layer containing an inorganic filler.

14. The method for manufacturing a plurality of thin wiring members according to claim 13,
wherein the thermosetting resin layer contains the inorganic filler in an amount of mass % or more and 90 mass % or less.

15. The method for manufacturing a plurality of thin wiring members according to claim 13,
wherein the inorganic filler has an average particle size of 0.05 μm or more.

16. The method for manufacturing a plurality of thin wiring members according to claim 1,
wherein the first carrier is a glass carrier having arithmetic average roughness Ra of 50 nm or less.

17. The method for manufacturing a plurality of thin wiring members according to claim 1,
wherein the wiring layer includes a wiring having a line width of 5 μm or less.

18. A thin wiring member comprising:
a wiring layer having a wiring and a resin composition present around the wiring or a cured product of the resin composition; and
a support layer disposed on a surface of the wiring layer,
wherein the support layer is formed of a material harder than the resin composition of the wiring layer or the cured product of the resin composition.

19. The thin wiring member according to claim 18,
wherein the wiring layer has a thickness of 200 μm or less,
the support layer has a thickness of 50 μm or more and 1200 μm or less, and
the wiring layer includes a wiring having a line width of 5 μm or less.

20. The thin wiring member according to claim 18,
wherein the support layer is formed of a material having a flexural modulus of 3 GPa or more.

21. The thin wiring member according to claim 18,
wherein the support layer includes a thermosetting resin layer containing an inorganic filler.

22. The thin wiring member according to claim 21,
wherein the thermosetting resin layer contains the inorganic filler in an amount of mass % or more and 90 mass % or less.

23. A method for manufacturing a wiring board, the method comprising:
preparing a thin wiring member manufactured by the method for manufacturing a plurality of thin wiring members according to claim 1;
placing the thin wiring member on a board or in the board; and
connecting the wiring of the thin wiring member to a connection terminal.
